(19) United States
(12) Patent Application Publication
(10) Pub. No.: US 2005/0104186 A1
(43) Pub. Date: May 19, 2005

(54) Chip-on-film package for image sensor and method for manufacturing the same

(75) Inventors: Charles Yang, Kaohsiung (TW); Allen Kuo, Kaohsiung (TW)

Correspondence Address: TROXELL LAW OFFICE PLLC, SUITE 1404, 5205 LEESBURG PIKE, FALLS CHURCH, VA, 22041, US

(73) Assignee: International Semiconductor Technology Ltd.

(21) Appl. No.: 10/706,997

(22) Filed: Nov. 14, 2003

(51) Int. Cl. H01L 29/22; H01L 23/48; H01L 31/00

(52) U.S. Cl. 257/688; 257/777; 257/690; 257/98; 257/431

(57) ABSTRACT

A chip-on-film (COF) package and method for image sensor has been disclosed. According to the method a COF film with opening is provided. The COF film has an upper surface, a lower surface and at least an opening. An image sensing chip is flip-chip mounted on the upper surface of the COF film. A transparent glass is bonded to the lower surface of the COF film. The opening is clipped by the transparent glass and the image sensing chip to form a hermetic space. The active surface of the image sensing chip includes an image sensing region toward the transparent glass through the opening and is sealed in the hermetic space by a limited filling material in order to prevent the image sensing region of the image sensing chip from contamination by means of COF tape packaging method.

### FIELD OF THE INVENTION

The present invention is relating to a package for image sensor, particularly to a chip-on-film package for image sensor and method for manufacturing the same.

### BACKGROUND OF THE INVENTION

Conventional image sensor includes a semiconductor chip with image sensing function (it will be abbreviated as image sensing chip below) for sensor of charge coupled device (CCD) or complementary metal oxide semiconductor (CMOS). The active surface of the image sensing chip is relatively sensitive to dust, so that it needs to be protected with a suitable package from invasion by dust and moisture. Conventional method for packaging image sensing chip is firstly to carry an image sensing chip on a hard medium such as leadframe or printed circuit board, then to be sealed by a glass cover and a dam. Practically, the leadframe or printed circuit board in plate-shape or strip-shape for image sensing chip shall be hard enough to form the dam during packaging process.

Alternatively a flip chip on glass image sensor package was disclosed in U.S. Pat. No. 6,342,406. An image sensing chip is flip-chip mounted onto a transparent glass. The transparent glass has conductive traces including signal input ends and signal output ends that are connected to each other by the conductive traces and are formed on different surface through vias in the transparent glass. After the image sensing chip is electrically connected to the signal input ends of the transparent glass by bumps, the transparent glass may be mounted to a printed circuit board with an opening, in other words, electrically connect the image sensing chip with printed circuit board through the signal output ends of the transparent glass. The transparent glass has to be pervious to light and has double-sided electrical conduction, but it is difficult and costs high to make electrically double-sided conductive traces on the transparent glass. Besides, a sealer will be provided to seal between the image sensing chip and the transparent glass without covering the image sensing region in the active surface. However, the size of the image-sensing chip is almost same as that of the transparent layer, so that the sealer is difficult to form by dispensing after electrically connecting the image sensing chip with the transparent glass.

An image sensing device package was disclosed in U.S. Pat. No. 6,071,760. Connecting an image sensing chip are a plurality of inner leads. The inner leads extend from an opening of flexible PI tape so that the image sensing chip is packaged by TAB bonding and tape conveying. The inner leads are suspended from the opening which is larger than the image sensing chip. Utilizing inner lead bonding (ILB) technique the inner leads are thermally pressed onto the bumps of the image sensing chip by means of a compression head. However, the image sensing chip is merely bonded to the suspended inner leads, so that the stability of the inner leads after bonding are not good enough to support the image sensing chip. Particularly, the request for horizontal control of active surface of image sensing chip is extremely severe, any slope of active surface that is caused while filling sealant is disadvantageous to the image sensor package.

### SUMMARY

The primary object of the present invention is to provide a chip-on-film (COF) package for image sensor, which includes an image sensing chip being flip-chip mounted on a COF film having an opening. The opening is small than active surface of the image sensing chip and larger than image sensing region in the active surface. The COF film has flip-chip connect pads on a surface of the film around the opening to join the image sensing chip, so that a filling material is easy to form periphery of the active surface without covering the image sensing region.

The secondary object of the present invention is to provide a chip-on-film (COF) package for image sensor, which includes a transparent glass and an image sensing chip larger than an opening of the COF film to clip lower and upper surfaces of the COF film respectively. A hermetic space is formed at the opening of the COF film so as to seal the image sensing region of the light-sensing chip under COF tape packaging process.

The third object of the present invention is to provide a chip-on-film (COF) package for image sensor having a filling material like ACP or NCP on the COF film for sealing the gap including image sensing region and covering the flip-chip bumps of the image sensing chip in order to enhance air tightness between image sensing chip and COF film.

In accordance with the present invention, a Chip-On Film package for image sensor comprises a COF film, an image sensing chip and a transparent glass. The COF film includes an insulating layer and a plurality of metal traces. The insulating layer has an upper surface, a lower surface and at least an opening. The opening is smaller than active surface of the image sensing chip and larger than image sensing region in the active surface. Each metal trace possesses a flip-chip connect pads. The flip-chip connect pads are disposed around the opening and attached on the upper surface, it is better that the flip-chip connect pads are electroplated to cover a metal layer such as gold or tin. The image sensing chip has a active surface and a plurality of flip-chip bumps are formed on periphery of the active surface. The image sensing chip is flip-chip mounted on the upper surface of the COF film, thereby to electrically connect the bumps of the image sensing chip with the flip-chip connect pads of the COF film. The transparent glass is fixed to the lower surface of the COF film corresponding to the opening, so that a hermetic gap is formed by the transparent glass and the image sensing chip. Preferably, before or after flip-chip mounting, a filling material, such as anisotropic conductive paste (ACP), non-conductive paste (NCP), anisotropic conductive film (ACF), non-conductive film (NCF), UV adhesive, or thermosetting filler, is disposed on the upper surface of the COF film. The filling material is confirmed around the opening in order to seal a gap between the COF film and the image sensing chip without covering the image sensing region.

### DESCRIPTION OF THE DRAWINGS

FIG. 1 is a flow chart of manufacturing a chip-on film package for image sensor in accordance with the present invention.

FIG. 2A to FIG. 2D are cross sectional views of COF film during the steps of manufacturing process of the chip-on-film package for image sensor in accordance with the first embodiment of the present invention.

FIG. 3A to FIG. 3D are cross sectional views of COF film during the steps of manufacturing process of the chip-on-film package for image sensor in accordance with the second embodiment of the present invention.

FIG. 4 is a cross sectional view of a chip-on-film package for image sensor in accordance with the third embodiment of the present invention.

### DETAILED DESCRIPTION OF THE PRESENT INVENTION

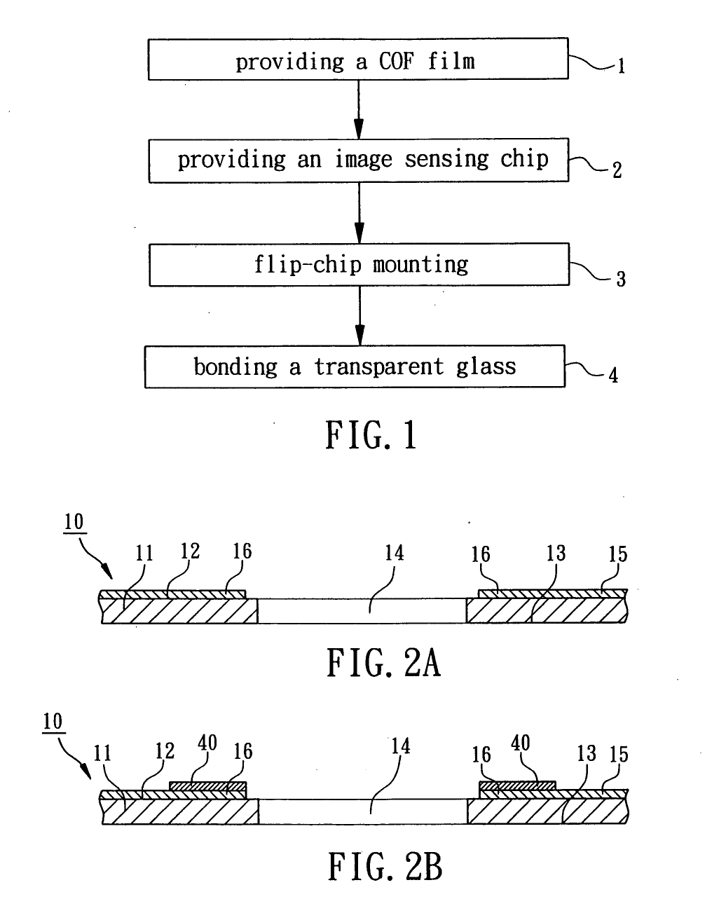

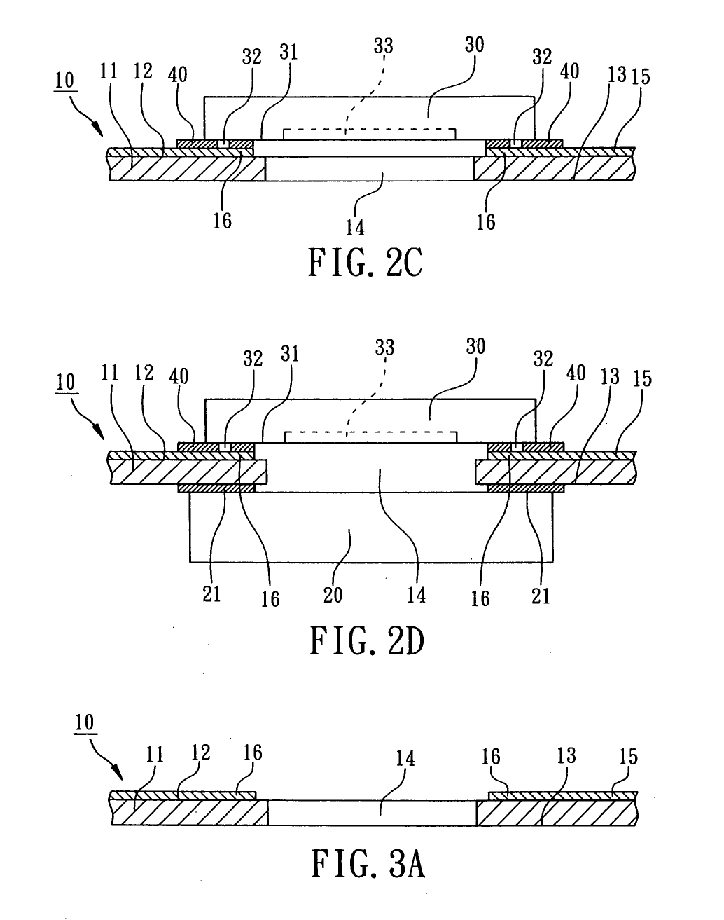

Referring to the drawings attached, the present invention will be described by means of the embodiments below. According to the first embodiment of the present invention, as showed in FIG. 1, a method for manufacturing a chip-on-film package for image sensor includes a step 1 of “providing a COF film”, a step 2 of “providing an image sensing chip”, a step 3 of “flip-chip mounting” and a step 4 of “bonding a transparent glass”. The chip-on-film package for image sensor as showed in FIG. 2D is manufactured by COF tape package manufacturing process. The chip-on-film package for image sensor includes a COF film 10 with wiring pattern. The COF film 10 is obtained from a COF tape that can be rolled up and conveyed by reel to reel. The COF film 10 includes an insulating layer 11 and a plurality of metal traces 15. The insulating layer 11 is flexible and electrically insulating and has a thickness approximately several ten micrometers. The insulating layer 11, is made of polyimide, polyester or other material, has an upper surface 12, a lower surface 13 and at least an opening 14. In this embodiment, the metal traces 15 are formed on the upper surface 12 and each metal trace 15 possesses a flip-chip connect pad 16. The flip-chip connect pads 16 are disposed around the opening 14 and attached on the upper surface 12. Preferably, formed on the connect pads 16 is a metal layer like gold, tin by electroplating. A transparent glass 20 is fixed on the lower surface 13 of the COF film 10 corresponding to the opening 14 by an adhesive film. An image sensing chip 30 with an active surface 31 is flip-chip mounted on the upper surface 12 of the COF film 10 corresponding to the opening 14. The active surface 31 includes an image sensing region 33 and a peripheral region surrounding the image sensing region 33. A plurality of pixels are formed on the image sensing region 33 to constitute a CMOS or CCD chip. The opening 14 of the COF film 10 should be larger than the image sensing region 33 but smaller than the active surface 31 in size. The image sensing region 33 is encompassed by the opening 14 and is toward the transparent glass 20. A plurality of flip-chip bumps 32 are formed on the peripheral region of the active surface 31 for connecting the flip-chip connect pads 16 of the COF film 10. In this embodiment, the flip-chip bumps 32 are non-reflowable conductive bumps that are made of gold, copper, aluminum or other alloy. Preferably, a filling material 40 is dispensed on the upper surface 12 of the COF film 10 for sealing the image sensing region 33 in a gap. The filling material 40 is selected from the group of anisotropic conductive paste (ACP), non-conductive paste (NCP), anisotropic conductive film (ACF), non-conductive film (NCF), UV adhesive, underfilling material, B-stage resin or other thermosetting compound, which is formed by liquid dispensing, potting or printing. In this embodiment, the filling material 40 is an anisotropic conductive paste (ACP) or non-conductive paste (NCP). Prior to curing the filling material 40, the filling material 40 is confined by the opening 14 for sealing the flip-chip mounting gap between the COF film 10 and the image sensing chip 30 without covering the image sensing region 33. Therefore, a hermetic gap is formed at the opening 14 of the COF film 10 to seal the the image sensing region 33 of the image sensing chip 30 by COF tape packaging technique.

According to the first embodiment, a COF film 10 is provided in the step 1 of “providing a COF film” as showed in FIG. 2A. The COF film 10 is formed from a COF tape by reel-to-reel conveyance. The COF film 10 has an upper surface 12, a lower surface 13 and openings 14 and connect pads 16 around the opening 14. Thereafter, step 2 of “providing a image sensing chip” and step 3 of “flip-chip mounting” will be executed. As showed in FIG. 2B, a filling material 40, such as ACP or NCP, is attached on the upper surface 12 of the COF film 10 for encompassing the opening 14 prior to the step 3 of “flip-chip mounting”. As showed in FIG. 2C, the provided image sensing chip 30 is flip-chip mounted to the COF film 10, thereby the flip-chip bumps 32 of the image sensing chip 30 are electrically connected to the flip-chip connect pads 16 of the COF film 10. Because that the filling material 40 is an anisotropic conductive paste (ACP) in the embodiment, conductive particles are contained inside the anisotropic conductive paste (ACP) so as to vertically electrical conduct without welding relationship. The flip-chip bumps 32 are unnecessarily welded with the flip-chip connect pads 16. After step 3 of “flip-chip mounting”, the filling material 40 is cured to seal the flip-chip bumps 32 without covering the image sensing region 33 under confinement of the opening 14. The joining between the COF film 10 and the image sensing chip 30 become stable, also the horizontal of the active surface 31 of the image sensing chip 30 can be maintained. Finally, step 4 of “bonding a transparent glass” is executed. As showed in FIG. 2D, a transparent glass 20 is attached to the lower surface 13 of the COF film 10 by adhesive film 21 in a manner that a hermetic gap is formed between the transparent glass 20 and the image sensing chip 30 corresponding to the opening 14 of the COF film 10. The image sensing region 33 of the image sensing chip 30 is airtight in the hermetic gap. The all four steps mentioned above are executed and conveyed by a COF tape for COF tape packaging process. Finally, each chip-on-film package for image sensor is formed after singulation. According to the method of the present invention, not only the active surface 31 of the image sensing chip 30 won't be easy to slope during COF packaging process in reel-to-reel tape conveyance, but also the image sensing region 33 of the image sensing chip 30 can be sealed by a filling material 40 during the COF packaging process.

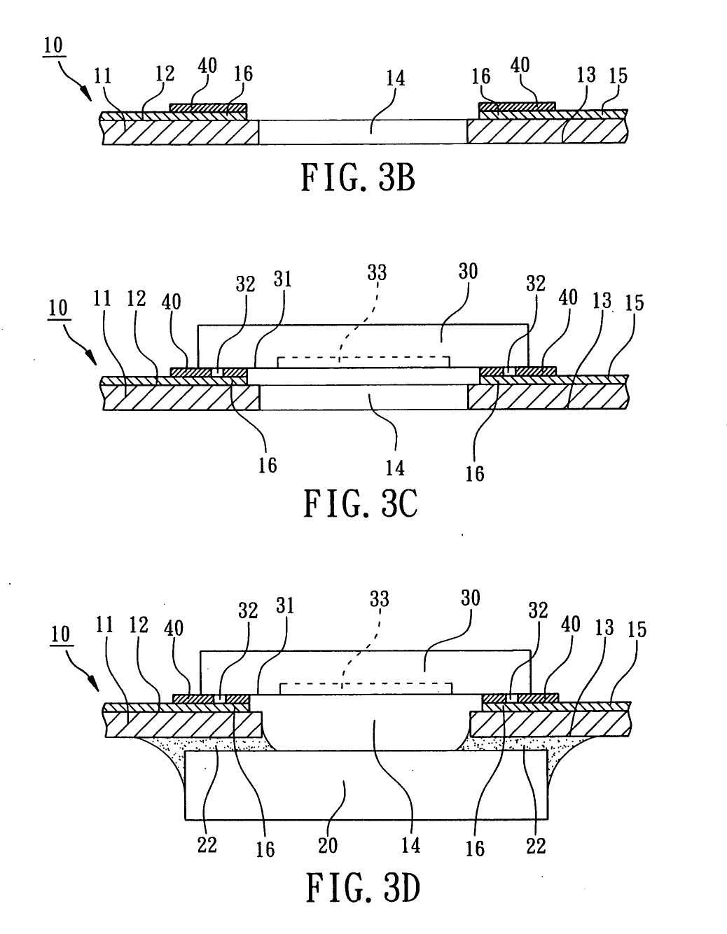

In the second embodiment of the present invention, another chip-on-film package for image sensor is showed in FIG. 3D is described as followed. The components in COF package being same or similar to those used in the first embodiment are presented by the same elements number, such as COF film 10, transparent glass 20, image sensing chip 30. The transparent glass 20 is adhered to the lower surface 13 of the COF film 10 by the thermosetting adhesive 22 like UV adhesive that is formed by liquid dispensing. The chip-on-film packaging process will be showed from FIG. 3A to FIG. 3D, the step 4 of “bonding a transparent glass” will be followed after the step 3 of “flip-chip mounting”. As showed in FIG. 3A a COF film 10 with an opening 14 is provided from a tape. As showed in FIG. 3B the image sensing chip 30 is flip-chip mounted to the upper surface 12 of the COF film 10. The opening 14 is larger than the image sensing region 33 of the image sensing chip 30 but smaller than the active surface 31. As showed in FIG. 3C a filling material 40 is dispensed on the upper surface 12 of the COF film 10 around the opening 14 for sealing the image sensing region 33. As showed in FIG. 3D, the transparent glass 20 is adhered to the lower surface 13 of the COF film 10 by thermosetting adhesive 22 that is formed by liquid dispensing. In this step 4, the COF film 10 may be conveyed as the upper surface 12 facing up or the lower surface 13 facing up, thereby a hermetic space is formed at the opening 14 for sealing the image sensing region 33 of the image sensing chip 30.

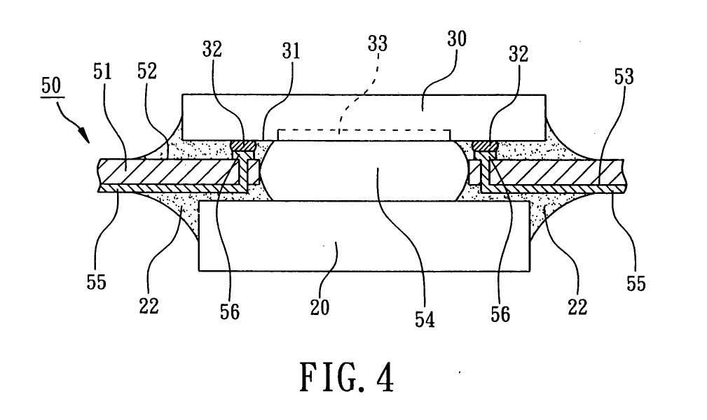

In the third embodiment of the present invention, as showed in FIG. 4, components disclosed in another COF package for image sensor which are same or similar to those used in the first embodiment are presented by the same elements number, such as transparent glass 20, image sensing chip 30. The COF package for image sensor includes a COF film 50, an image sensing chip 30 and a transparent glass 20. The COF film 50 comprises an electrically insulating layer 51 and a plurality of metal traces 55. The metal traces 55 are formed on the lower surface 53 of the electrically insulating layer 51 and each metal trace 55 connects a flip-chip connect pad 56 on the upper surface 52 of the electrically insulating layer 51 by passing through via. The flip-chip connect pads 56 are disposed around the opening 54 and substantially attached to the electrically insulating layer 51. The image sensing chip 30 is flip-chip mounted on the upper surface 52 of the COF film 50. In this embodiment, the flip-chip bumps 32 of the image sensing chip 30 are reflowable tin-lead bumps and mounted to the flip-chip connect pads 56. The active surface 31 of the image sensing chip 30 faces to the transparent glass 20, the transparent glass 20 is corresponding to the opening 54 and fixed to the lower surface 53 of the COF film 50. In the step 4 of “bonding a transparent glass”, a thermosetting adhesive 22 formed by liquid dispensing like UV adhesive or flip-chip underfilling material is used for dispensing at the perimeter of the transparent glass 20. The thermosetting adhesive 22 flows on the upper surface 52 of the COF film 50 and covers the flip-chip bumps 32 because of capillary effect. Then, the transparent glass 20 is bonded to the COF film 50 by curing the thermosetting adhesive 22, thereby to simplify the filling material 40 and keep the sealing efficiency around the opening 54 to seal the image sensing region 33.

The above description of embodiments of this invention is intended to be illustrated are not limiting. Other embodiments of this invention will be obvious to those skilled in the art in view of the above disclosure.

1. A chip-on-film package for image sensor comprising:
a chip-on-film (COF) film including an electrically insulating layer and a plurality of metal traces, the insulating layer having an upper surface, a lower surface and at least an opening, each metal trace having a connect pad, the connect pads being disposed around the opening on the upper surface;
an image sensing chip being mounted on the upper surface of the COF film, the image sensing chip having an active surface, the active surface includes an image sensing region being aligned with the opening, the image sensing chip having a plurality of flip-chip bumps at perimeter of the active surface, the flip-chip bumps being electrically connected with the connect pads; and
a transparent glass bonded to the lower surface of the COF film corresponding to the opening so as to form a hermetic gap between the transparent glass and the image sensing chip.

2. The package in accordance with claim 1, wherein the opening is larger than the image sensing region of the image sensing chip but smaller than the active surface.

3. The package in accordance with claim 2, further comprising a filling material formed on the upper surface of the COF film to fill around the opening, thereby to seal the gap.

4. The package in accordance with claim 3, wherein the filling material is an anisotropic conductive paste (ACP) or non-conductive paste (NCP).

5. The package in accordance with claim 3, wherein the filling material is an anisotropic conductive film (ACF) or non-conductive film (NCF).

6. The package in accordance with claim 3, wherein the filling material is a thermosetting adhesive or UV adhesive formed by dispensing.

7. The package in accordance with claim 1, wherein the metal traces are formed on the upper surface of the electrically insulating layer.

8. The package in accordance with claim 1, wherein a metal layer is formed over the connect pads.

9. A method for making a chip-on-film package for image sensor comprising the steps of:
providing a chip-on-film (COF) film including an electrically insulating layer and a plurality of metal traces, the insulating layer having an upper surface, a lower surface and at least an opening, each metal trace having a connect pad, the connect pads being disposed around the opening on the upper surface;
mounting an image sensing chip on the upper surface of the COF film, the image sensing chip having an active surface, the active surface includes an image sensing region being aligned with the opening, the image sensing chip having a plurality of flip-chip bumps at perimeter of the active surface, the flip-chip bumps being electrically connected with the connect pads; and
bonding a transparent glass to the lower surface of the COF film corresponding to the opening so as to form a hermetic gap between the transparent glass and the image sensing chip.

10. The method in accordance with claim 9, wherein the opening is larger than the image sensing region of the image sensing chip but smaller than the active surface.

11. The method in accordance with claim 10, further comprising: the step of forming a filling material on the upper surface of the COF film to fill around the opening, thereby to seal the gap.

12. The method in accordance with claim 11, wherein the filling material is an anisotropic conductive paste (ACP) or non-conductive paste (NCP).

13. The method in accordance with claim 11, wherein the filling material is an anisotropic conductive film (ACF) or non-conductive film (NCF).

14. The method in accordance with claim 11, wherein the filling material is a thermosetting adhesive or UV adhesive formed by dispensing.

15. The method in accordance with claim 9, wherein the metal traces are formed on the upper surface of the electrically insulating layer.

16. The method in accordance with claim 9, wherein a metal layer is formed over the connect pads.
